(19) United States
(12) Patent Application Publication
(10) Pub. No.: US 2015/0069592 A1
(43) Pub. Date: Mar. 12, 2015

(54) SEMICONDUCTOR DEVICE, METHOD OF MANUFACTURING SAME, AND APPLICATION BOARD MOUNTED WITH SAME

(71) Applicant: Kabushiki Kaisha Toshiba, Tokyo (JP)

(72) Inventors: Koji Tamura, Himeji-Shi (JP); Nobuyuki Sato, Nonoichi-Shi (JP); Nobuhiro Shingai, Himeji-Shi (JP); Shinya Ozawa, Kanazawa-Shi (JP); Takeru Matsuoka, Himeji-Shi (JP); Hideki Okumura, Nonoichi-Shi (JP)

(73) Assignee: Kabushiki Kaisha Toshiba, Tokyo (JP)

(21) Appl. No.: 14/199,515

(22) Filed: Mar. 6, 2014

(30) Foreign Application Priority Data
Sep. 6, 2013 (JP) 2013-185616

(51) Int. Cl. H01L 23/495

(52) U.S. Cl. CPC H01L 23/49517; H01L 23/49575
USPC 257/676; 438/123

(57) ABSTRACT

In one embodiment, a semiconductor device includes a lead frame including an island portion and a terminal portion separated from the island portion. The device further includes a semiconductor chip mounted on the island portion and including an electrode. The device further includes an insulating layer disposed on the semiconductor chip and having an opening to expose at least a part of the electrode. The device further includes a connector covering the electrode exposed through the opening and electrically connecting the electrode and the terminal portion.

### CROSS REFERENCE TO RELATED APPLICATION

This application is based upon and claims the benefit of priority from the prior Japanese Patent Application No. 2013-185616, filed on Sep. 6, 2013, the entire contents of which are incorporated herein by reference.

### FIELD

Embodiments described herein relate to a semiconductor device, a method of manufacturing the same, and an application board mounted with the same.

### BACKGROUND

In a semiconductor device, a semiconductor chip is sealed up with a molding resin. If the semiconductor device is stored for a long period in a state that the semiconductor device is exposed to air, the molding resin absorbs moisture in the air. Consequently, semiconductor elements on the semiconductor chip may deteriorate due to this moisture.

### BRIEF DESCRIPTION OF THE DRAWINGS

FIGS. 1A and 1B are drawings of a semiconductor device of a first embodiment;

FIG. 2 is a flowchart showing a method of manufacturing the semiconductor device of the first embodiment;

FIGS. 3A and 3B are drawings of an application board mounted with the semiconductor device of the first embodiment; and

FIGS. 4A and 4B are drawings of a semiconductor device of a second embodiment.

### DETAILED DESCRIPTION

Embodiments will now be explained with reference to the accompanying drawings. The present invention is not limited to these embodiments. Common components are denoted by common reference numerals throughout the drawings, and duplicate descriptions of these components are omitted. The drawings are schematic views used to facilitate the description and understanding of the invention, and may therefore differ from actual devices in shape, dimension, ratio and the like in some places. Design changes can be made to these devices as appropriate by taking into consideration the following description and known technology. In the following embodiments, a vertical direction of a semiconductor chip indicates a relative direction when a surface of the semiconductor chip where semiconductor elements are arranged is faced up, and may therefore differ from a vertical direction based on the gravitational acceleration in some cases.

In one embodiment, a semiconductor device includes a lead frame including an island portion and a terminal portion separated from the island portion. The device further includes a semiconductor chip mounted on the island portion and including an electrode. The device further includes an insulating layer disposed on the semiconductor chip and having an opening to expose at least a part of the electrode. The device further includes a connector covering the electrode exposed through the opening and electrically connecting the electrode and the terminal portion.

### First Embodiment

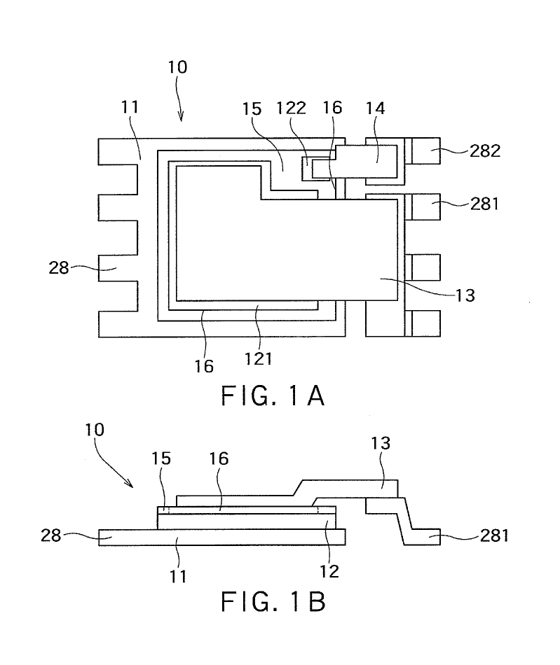

FIGS. 1A and 1B are drawings of a semiconductor device 10 of a first embodiment.

FIG. 1A illustrates a top view of the semiconductor device 10, and FIG. 1B illustrates a side view of the semiconductor device 10 on a first sheet-like connector 13 side.

The semiconductor device 10 includes a lead frame 11, a semiconductor chip 12, an insulating layer 15, a first sheet-like connector 13, and a second sheet-like connector 14.

The lead frame 11 includes an island portion 28, and first and second terminal portions 281 and 282 separated from the island portion 28. The lead frame 11 is made of an electrical conductor and formed of, for example, low-resistance metal. The island portion 28 is a mounting portion on which the semiconductor chip 12 is mounted. The first and second terminal portions 281 and 282 are electrically connected to first and second electrodes 121 and 122 of the semiconductor chip 12.

The semiconductor chip 12 is mounted on the island portion 28, and includes the first and second electrodes 121 and 122. The type of the semiconductor chip 12 is optional, and therefore not limited in particular. The insulating layer 15 is formed on the semiconductor chip 12 and includes openings 16. The insulating layer 15 is formed of, for example, polyimide. In the first embodiment, the openings 16 have shapes and sizes corresponding to shapes and sizes of the first and second electrodes 121 and 122 to expose the first and second electrodes 121 and 122 in whole.

The first sheet-like connector 13 is a bent, belt-like metal sheet. Similarly to the openings 16, the first sheet-like connector 13 has a shape and a size corresponding to the shape and the size of the first electrode 121. Accordingly, one end of the first sheet-like connector 13 covers almost the entire area of the first electrode 121 exposed through the opening 16. The other end of the first sheet-like connector 13 is in contact with the first terminal portion 281 of the lead frame 11. In this manner, the first sheet-like connector 13 electrically connects the first electrode 121 and the first terminal portion 281. In addition, similarly to the openings 16, the first sheet-like connector 13 has the shape and the size corresponding to the shape and the size of the first electrode 121. The connector 13 can therefore cover the first electrode 121 in whole. Consequently, it is possible to widen the area of contact between the first sheet-like connector 13 and the first electrode 121. It is therefore possible to lower the contact resistance between the first sheet-like connector 13 and the first electrode 121.

Similarly to the first sheet-like connector 13, the second sheet-like connector 14 is also a bent, belt-like metal sheet. Similarly to the openings 16, the second sheet-like connector 14 has a shape and a size corresponding to the shape and the size of the second electrode 122. Accordingly, one end of the second sheet-like connector 14 covers almost the entire area of the second electrode 122 exposed through the opening 16. The other end of the second sheet-like connector 14 is in contact with the second terminal portion 282 of the lead frame 11. In this manner, the second sheet-like connector 14 electrically connects the second electrode 122 and the second terminal portion 282. In addition, similarly to the openings 16, the second sheet-like connector 14 has the shape and the size corresponding to the shape and the size of the second electrode 122. The connector 14 can therefore cover the second electrode 122 in whole. Consequently, it is possible to widen the area of contact between the second sheet-like connector 14 and the second electrode 122. It is therefore possible to lower the contact resistance between the second sheet-like connector 14 and the second electrode 122.

Here, the semiconductor chip 12, the first and second sheet-like connectors 13 and 14 and the like of the semiconductor device 10 are not sealed up with a molding resin. In a case where an electrical connection is made between an electrode of the semiconductor chip and a terminal portion of the lead frame with a wire having a thread-like structure, the wire having the thread-like structure becomes easily deformed if a force is applied from outside the semiconductor device. The deformation of the wire may lead to disconnection or short-circuiting with other wires. Accordingly, in the semiconductor device, the wire needs to be immobilized with a molding resin to avoid causing the wire to become deformed. The molding resin also has a function of protecting the semiconductor chip against contamination by covering the surfaces of the semiconductor chip.

However, since the molding resin has hygroscopicity as described above, the molding resion absorbs moisture in the air. Accordingly, semiconductor elements on the semiconductor chip may deteriorate due to the moisture.

Therefore, the semiconductor device 10 of the first embodiment includes the first and second sheet-like connectors 13 and 14 in place of wires. The first and second sheet-like connectors 13 and 14 are metal sheets having a sheet-like structure and higher in mechanical strength than wires having a thread-like structure. Accordingly, the first and second sheet-like connectors 13 and 14 are unlikely to be deformed by an external force. The first and second sheet-like connectors 13 and 14 therefore need not be immobilized with a molding resin.

In the semiconductor device 10, the first and second electrodes 121 and 122 are covered with the first and second sheet-like connectors 13 and 14, and surfaces of the semiconductor chip 12 other than those of the first and second electrodes 121 and 122 are covered with the insulating layer 15. Consequently, the surfaces of the semiconductor chip 12 including the first and second electrodes 121 and 122 are protected by the insulating layer 15 and the first and second sheet-like connectors 13 and 14. Accordingly, there is no need in the semiconductor device 10 to provide a molding resin for protecting the surfaces of the semiconductor chip 12.

For the above-described reason, the semiconductor device 10 of the first embodiment need not be sealed up with a molding resin. Since the semiconductor device 10 therefore does not include any molding resin having hygroscopicity, it is possible to prevent the deterioration of semiconductor elements due to moisture.

In addition, the first and second sheet-like connectors 13 and 14 are wider in cross-sectional area than wires, and therefore superior in electrical conductivity. Accordingly, the first and second electrodes 121 and 122 and the first and second terminal portions 281 and 282 can be electrically connected with low resistance by using the first and second sheet-like connectors 13 and 14.

(1) Method of Manufacturing Semiconductor Device

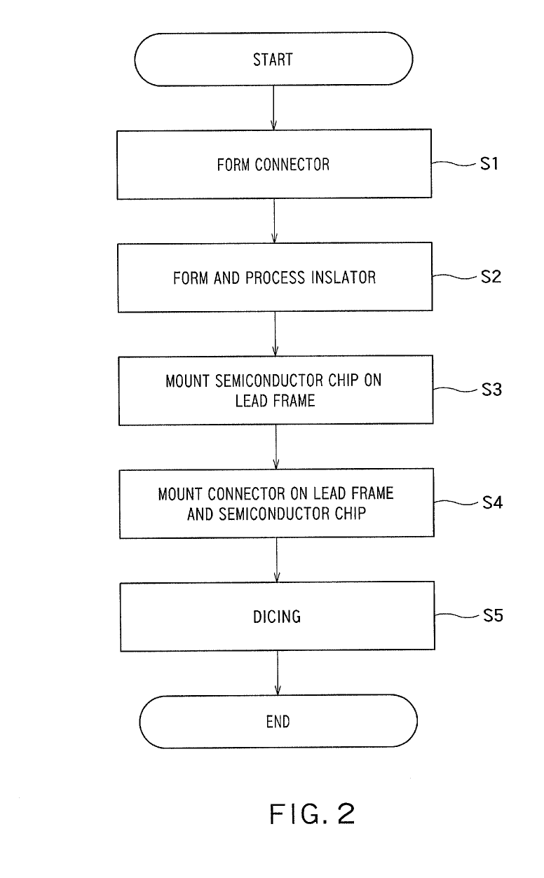

FIG. 2 is a flowchart showing a method of manufacturing the semiconductor device 10 of the first embodiment.

In step S1, a metal sheet is pressed, etched and cut to form the first and second sheet-like connectors 13 and 14. At this time, the first and second sheet-like connectors 13 and 14 are formed so as to correspond in shape and size to the first and second electrodes 121 and 122. Consequently, when the first and second sheet-like connectors 13 and 14 are connected respectively onto the first and second electrodes 121 and 122 of the semiconductor chip 12, the first and second sheet-like connectors 13 and 14 can cover the entire areas of the first and second electrodes 121 and 122.

In step S2, the insulating layer 15 is formed on the semiconductor chip 12. In addition, the openings 16 to expose the entire areas of the first and second electrodes 121 and 122 on the semiconductor chip 12 are formed in the insulating layer 15.

In step S3, the semiconductor chip 12 is mounted on the island portion 28 of the lead frame 11 by using a conductive adhesive agent.

In step S4, the first sheet-like connector 13 is fixed onto the first electrode 121 exposed through an opening 16 and onto the first terminal portion 281 by using a conductive adhesive agent. Likewise, the second sheet-like connector 14 is fixed onto the second electrode 122 exposed through an opening 16 and onto the second terminal portion 282.

In step S5, a plurality of semiconductor devices 10 coupled by the lead frame 11 is uncoupled (divided into individual pieces).

Consequently, each semiconductor device 10 is completed. According to this manufacturing method, since the semiconductor device is not sealed up with a molding resin, it is possible to reduce manufacturing process steps and manufacturing costs.

(2) Application Board

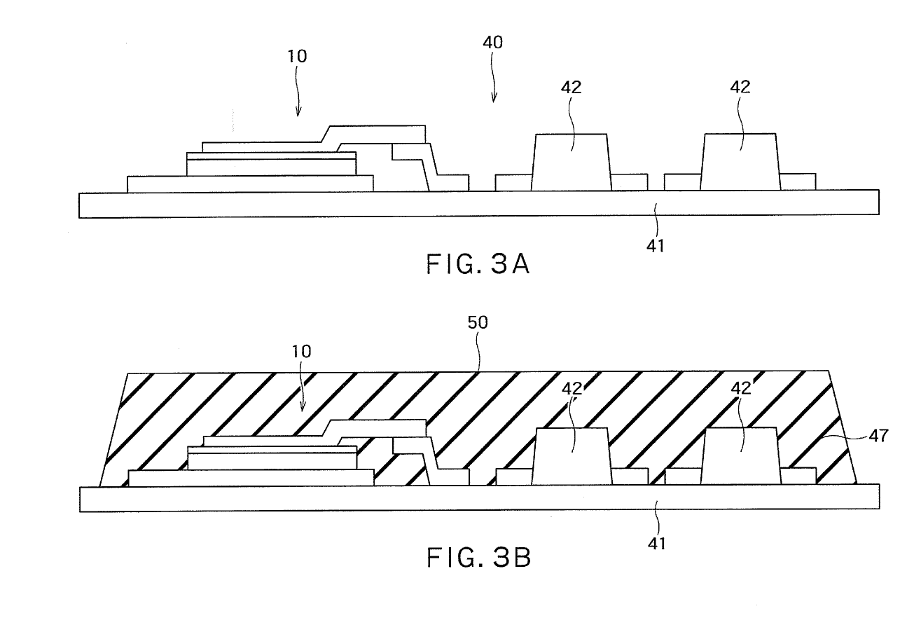

FIGS. 3A and 3B are drawings of an application board mounted with the semiconductor device 10 of the first embodiment.

FIGS. 3A and 3B respectively illustrate examples of an application board 40 including the semiconductor device 10 of the first embodiment.

As illustrated in FIG. 3A, the application board 40 includes a substrate 41, the semiconductor device 10, and a plurality of electronic components 42. The substrate 41 may be, for example, a printed circuit board. The electronic components 42 are electrically connected to the semiconductor device 10 via wiring patterns on the printed circuit board 41. In addition, the printed circuit board 41, the semiconductor device 10, and the plurality of electronic components 42 may be integrally sealed up with a molding resin 47 to obtain such an application board 50 as illustrated in FIG. 3B.

According to the first embodiment, since the semiconductor device 10 uses the first and second sheet-like connectors 13 and 14 which are high in mechanical strength, the semiconductor device 10 can avoid suffering short-circuit and disconnection faults without having to be sealed up with a molding resin. In addition, according to the first embodiment, the first and second electrodes 121 and 122 are covered with the first and second sheet-like connectors 13 and 14, and the surfaces of the semiconductor chip 12 other than those of the first and second sheet-like connectors 13 and 14 are covered with the insulating layer 15. Accordingly, it is possible to protect the surfaces of the semiconductor chip 12 including the first and second electrodes 121 and 122 without having to seal up the surfaces with a molding resin.

For the above-described reason, according to the first embodiment, there is no need to seal up the semiconductor device 10 with a molding resin. Since the semiconductor device 10 therefore does not include any molding resin having hygroscopicity, it is possible to prevent the deterioration of semiconductor elements due to moisture.

According to the first embodiment, since the semiconductor device is not sealed up with a molding resin, it is possible to reduce manufacturing process steps and manufacturing costs.

According to the first embodiment, the first and second electrodes 121 and 122 and the first and second terminal portions 281 and 282 can be electrically connected with low resistance by using the first and second sheet-like connectors 13 and 14 superior in electrical conductivity to wires

### Second Embodiment

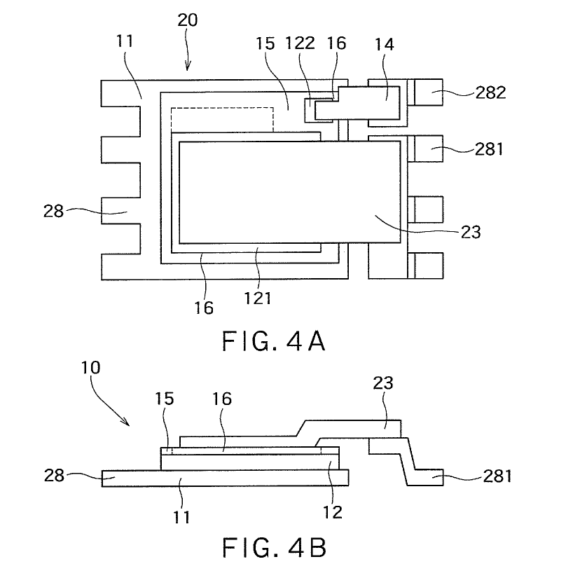

FIGS. 4A and 4B are drawings of a semiconductor device 20 of a second embodiment.

FIG. 4A illustrates a top view of the semiconductor device 20 of the second embodiment, and FIG. 4B illustrates a side view of the semiconductor device 20 of the second embodiment on a first sheet-like connector 23 side.

The second embodiment differs from the first embodiment in the shape of the first sheet-like connector 23. The rest of the configuration of the second embodiment may be the same as the corresponding configuration of the first embodiment. The connecting portion of the first sheet-like connector 23 connected to the first electrode 121 is formed so as to correspond in shape and size to an opening 16 of the insulating layer 15 rather than to the first electrode 121. Accordingly, the first sheet-like connector 23 covers the first electrode 121 not in whole but in part in a case where the first electrode 121 is partially exposed through the opening 16. That is, the first electrode 121 is covered in whole with both the first sheet-like connector 23 and the insulating layer 15. In FIG. 4A, the area of the first electrode 121 covered with the insulating layer 15 is shown by a dashed line.

Conversely, the opening 16 of the insulating layer 15 is formed so as to correspond in shape and size to the first sheet-like connector 23 rather than to the first electrode 121.

The first electrode 121 may vary in shape and size for each product. Accordingly, in order to make the first sheet-like connector 13 correspond in shape and size to the first electrode 121 of each product to cover the entire area of the first electrode 121, the first sheet-like connector 13 needs to be manufactured as a dedicated connector on a product-by-product basis.

In contrast, according to the second embodiment, the first electrode 121 is covered in whole with both the first sheet-like connector 23 and the insulating layer 15. That is, the first sheet-like connector 23 covers a part of the first electrode 121, and the insulating layer 15 covers the rest of the first electrode 121. Accordingly, the first sheet-like connector 23 need not be made to correspond in shape and size to the first electrode 121, while the first sheet-like connector 23 need be made to correspond in shape and size to the opening 16. It is therefore possible to apply the same shape and size of the first sheet-like connector 23 to different products. Consequently, the first sheet-like connector 23 can be mass-produced not as a dedicated connector but as a general-purpose connector usable for a wide range of products. This enables a reduction in the manufacturing costs of the connector. Similarly to the first sheet-like connector, the second sheet-like connector 14 can also be manufactured as a general-purpose connector for partially covering the second electrode 122.

According to the second embodiment, there is no need for sealing with a molding resin as similar to the first embodiment. Consequently, it is possible to obtain the same effects as those of the first embodiment. In the second embodiment, the entire surfaces of the semiconductor chip 12 including the first and second electrodes 121 and 122 are covered with the insulating layer 15 and the first and second sheet-like connectors 23 and 14. Accordingly, the surfaces of the semiconductor chip 12 including the first and second electrodes 121 and 122 can be protected without having to seal up the semiconductor chip with a molding resin.

While certain embodiments have been described, these embodiments have been presented by way of example only, and are not intended to limit the scope of the inventions. Indeed, the novel devices, methods and boards described herein may be embodied in a variety of other forms; furthermore, various omissions, substitutions and changes in the form of the devices, methods and boards described herein may be made without departing from the spirit of the inventions. The accompanying claims and their equivalents are intended to cover such forms or modifications as would fall within the scope and spirit of the inventions.

1. A semiconductor device comprising:
a lead frame including an island portion and a terminal portion separated from the island portion;
a semiconductor chip mounted on the island portion and including an electrode;
an insulating layer disposed on the semiconductor chip and having an opening to expose at least a part of the electrode; and
a connector covering the electrode exposed through the opening and electrically connecting the electrode and the terminal portion.

2. The device of claim 1, wherein the opening and the connector have shapes and sizes corresponding to a shape and a size of the electrode.

3. The device of claim 2, wherein the opening exposes the electrode in whole.

4. The device of claim 1, wherein the connector has a shape and a size corresponding to a shape and a size of the opening.

5. The device of claim 4, wherein the opening exposes only a part of the electrode.

6. The device of claim 1, wherein the connector is fixed onto the electrode and the terminal portion with a conductive adhesive agent.

7. A method of manufacturing a semiconductor device, comprising:
mounting a semiconductor chip including an electrode on an island portion of a lead frame;
forming an insulating layer having an opening to expose at least a part of the electrode on the semiconductor chip; and
arranging a connector which electrically connects the electrode and a terminal portion of the lead frame, so as to cover the electrode exposed through the opening, the terminal portion being separated from the island portion.

8. The method of claim 7, wherein the opening and the connector have shapes and sizes corresponding to a shape and a size of the electrode.

9. The method of claim 8, wherein the opening exposes the electrode in whole.

10. The method of claim 7, wherein the connector has a shape and a size corresponding to a shape and a size of the opening.

11. The method of claim 10, wherein the opening exposes only a part of the electrode.

12. The method of claim 7, wherein the connector is fixed onto the electrode and the terminal portion with a conductive adhesive agent.

13. An application board mounted with a semiconductor device and an electronic component, the semiconductor device comprising:
a lead frame including an island portion and a terminal portion separated from the island portion;
a semiconductor chip mounted on the island portion and including an electrode;
an insulating layer disposed on the semiconductor chip and having an opening to expose at least a part of the electrode; and
a connector covering the electrode exposed through the opening and electrically connecting the electrode and the terminal portion.

14. The board of claim 13, further comprising a molding resin which integrally seals up the semiconductor device and the electronic component.

15. The board of claim 13, wherein the semiconductor device and the electronic component are disposed on the same substrate and electrically connected to each other via a wiring pattern on the substrate.

16. The device of claim 13, wherein the opening and the connector have shapes and sizes corresponding to a shape and a size of the electrode.

17. The device of claim 16, wherein the opening exposes the electrode in whole.

18. The device of claim 13, wherein the connector has a shape and a size corresponding to a shape and a size of the opening.

19. The device of claim 18, wherein the opening exposes only a part of the electrode.

20. The device of claim 13, wherein the connector is fixed onto the electrode and the terminal portion with a conductive adhesive agent.
